(19) United States
(12) Patent Application Publication
(10) Pub. No.: US 2026/0323812 A1
(43) Pub. Date: Oct. 15, 2026

(54) CIRCUIT BOARD AND DISPLAY DEVICE

(71) Applicants: Chongqing BOE Display Technology Co., Ltd., Chongqing (CN); BOE TECHNOLOGY GROUP CO., LTD., Beijing (CN); BEIJING BOE TECHNOLOGY DEVELOPMENT CO., LTD., Beijing (CN)

(72) Inventors: Chuanyong Li, Beijing (CN); Xuerui Gong, Beijing (CN); Wenhong Liu, Beijing (CN); Yong Yu, Beijing (CN); Qun Jia, Beijing (CN); Jie Yang, Beijing (CN); Bowen Xiao, Beijing (CN); Yanli Wang, Beijing (CN); Chunyan LI, Beijing (CN)

(73) Assignees: Chongqing BOE Display Technology Co., Ltd., Chongqing (CN); BOE TECHNOLOGY GROUP CO., LTD., Beijing (CN); Beijing BOE Technology Development Co., Ltd., Beijing (CN)

(21) Appl. No.: 19/476,516

(22) PCT Filed: Oct. 30, 2024
(86) PCT No.: PCT/CN2024/128612

§ 371 Date: Oct. 17, 2025

(30) Foreign Application Priority Data
Nov. 30, 2023 (CN) 202311634973.6

(51) Int. Cl. H05K 1/02; H05K 7/20

(52) U.S. Cl. CPC H05K 1/0206; H05K 7/20963; H05K 2201/10128

(57) ABSTRACT

Provided is a circuit board, including a pad and a circuit board body, the circuit board body includes at least two thermal conduction layers, a first conducting portion is respectively connected to the pad and the thermal conduction layer, and a second conducting portion is respectively connected to two adjacent thermal conduction layers. Heat of the pad may be transferred to the thermal conduction layer through the first conducting portion, and heat may be transferred among the thermal conduction layers through the second conducting portion, so that heat may be transferred longitudinally among thermal conduction layers. At least two of any two conducting portions adjacent along a longitudinal direction are staggered with each other. A display device including the above circuit board is further provided.

### CROSS REFERENCE TO RELATED APPLICATION(S)

This application is a Section 371 National Stage Application of International Application No. PCT/CN 2024/128612 filed on Oct. 30, 2024, which claims priority to Chinese Patent Application No. 202311634973.6, filed on Nov. 30, 2023, entitled “CIRCUIT BOARD AND DISPLAY DEVICE”, the entire contents of which are incorporated herein by reference in its entireties.

### TECHNICAL FIELD

The present disclosure relates to the field of display technologies, and in particular to a circuit board and a display device.

### BACKGROUND

In aviation, in-vehicle, industrial control and other application scenarios that require high reliability of a display module, long-time lighting of the display module results in high heat generation in the power management chip, MOS tube, and inductor on the circuit board.

Currently, heat in areas where the pads of these components are located on the circuit board may not be effectively dissipated, which easily forms high-temperature hot spots. In severe cases, this may cause the display function problem of yellowing of the display region of the display panel, which affects the display effect.

It should be noted that the information disclosed in the above background technology section is only used to enhance understanding of the background of the present disclosure, and therefore may include information that does not constitute the prior art known to those of ordinary skill in the art.

### SUMMARY

The objective of the present disclosure is to solve problems in the prior art, and a circuit board and a display device are provided.

According to an aspect of the present disclosure, a circuit board is provided, including: a circuit board body; a binding layer on a side of the circuit board body, the binding layer includes a pad and a lead, the pad is configured to bind an electronic component, the lead is connected to the pad and configured to transmit an electrical signal to the pad, or transmit an electrical signal from the pad to an interior of the circuit board. The circuit board body includes at least two thermal conduction layers, an insulating layer is provided between the pad and one of the at least two thermal conduction layers or between two adjacent thermal conduction layers, the insulating layer are provided with a via filled with a conducting portion, the conducting portion between the pad and the thermal conduction layer is a first conducting portion respectively connected to the pad and the thermal conduction layer, the conducting portion between two adjacent thermal conduction layers is a second conducting portion respectively connected to the two adjacent thermal conduction layers, at least two of any two conducting portions adjacent along a longitudinal direction are staggered with each other, and the longitudinal direction is a thickness direction of the circuit board body.

In an embodiment of the present disclosure, the pad includes a first pad, the lead includes a reference signal line connected to the first pad and configured to input a reference signal to the first pad, the thermal conduction layer includes a first thermal conduction sub-layer, a first via is provided between the first pad and the first thermal conduction sub-layer, the first via is filled with the first conducting portion, and the first conducting portion is respectively connected to the first pad and the first thermal conduction sub-layer.

In an embodiment of the present disclosure, the pad includes a second pad, the lead includes a high-level signal line connected to the second pad and configured to input a high-level signal to the second pad, the thermal conduction layer includes a second thermal conduction sub-layer, the second thermal conduction sub-layer is insulated from the first thermal conduction sub-layer, the first via is further provided between the second pad and the second thermal conduction sub-layer, the first via is filled with the first conducting portion, and the first conducting portion is respectively connected to the second pad and the second thermal conduction sub-layer.

In an embodiment of the present disclosure, at least two first conducting portions are provided between the pad and the thermal conduction layer, and second conducting portions identical in number as the first conducting portions are provided between every two adjacent thermal conduction layers, each of the at least two first conducting portions and each of the second conducting portions closest to the first conducting portion is located on a same straight line in a longitudinal direction, and the longitudinal direction is the thickness direction of the circuit board body.

In an embodiment of the present disclosure, at least one first conducting portion is provided between the pad and the thermal conduction layer, and two second conducting portions are provided between two adjacent thermal conduction layers and located on two sides of the first conducting portion, and a distance between two second conducting portions gradually increases in a direction away from the pad.

In an embodiment of the present disclosure, the thermal conduction layer farthest from the pad is a first thermal conduction layer, a first hollow portion is provided on the first thermal conduction layer, and an orthographic projection of the pad on the first thermal conduction layer is located within the first hollow portion.

In an embodiment of the present disclosure, the rest of the thermal conduction layers are second thermal conduction layers, and the second conducting portions between the first thermal conduction layer and an adjacent second thermal conduction layer are provided on two sides of the first hollow portion.

In an embodiment of the present disclosure, a third via is provided between second vias of at least part of insulating layers, the third via is filled with a third conducting portion, the third conducting portion is respectively connected to two adjacent thermal conduction layers, and the third conducting portion is provided between two second conducting portions of a same insulating layer.

In an embodiment of the present disclosure, the number of the third conducting portion gradually increases in a direction away from the pad.

In an embodiment of the present disclosure, in the same insulating layer, a distance between any two adjacent conducting portions is equal, and the distance between adjacent conducting portions gradually decreases in the direction away from the pad.

In an embodiment of the present disclosure, the number of the third conducting portions is alternately provided in an even number and an odd number, the thermal conduction layer farthest from the pad is provided with an even number of third conducting portions, and a first hollow portion is provided between two third conducting portions closest to a straight line where the first conducting portion is located.

In an embodiment of the present disclosure, a cross-sectional area of the first conducting portion gradually increases from a middle portion of the first conducting portion toward two ends of the first conducting portion, and a cross-sectional area of the second conducting portion gradually increases from a middle portion of the second conducting portion toward two ends of the second conducting portion.

According to another aspect of the present disclosure, a display device is provided, including: a display module and the circuit board according to an aspect of the present disclosure. The display module includes a display panel, a middle frame and a heat dissipation mechanism. The circuit board is connected to the display panel, an edge of the circuit board exceeding at least one side of the display panel in a transverse direction to form an exposed portion connected to the middle frame and/or the heat dissipation mechanism.

In an embodiment of the present disclosure, the thermal conduction layer closest to the display panel is the first thermal conduction layer, and the exposed portion is located on a portion of the first thermal conduction layer exceeding at least one side edge of the display panel in the transverse direction.

In an embodiment of the present disclosure, the first thermal conduction layer is provided with a second hollow portion, an orthographic projection of the display panel on the first thermal conduction layer is located within the second hollow portion, and exposed portions are located on two sides of the second hollow portion.

### BRIEF DESCRIPTION OF THE DRAWINGS

The accompanying drawings, which are incorporated in and constitute a part of the specification, illustrate embodiments consistent with the present disclosure and, together with the specification, serve to explain the principles of the present disclosure. Obviously, the drawings described below are only some embodiments of the present disclosure. Those of ordinary skill in the art may obtain other drawings based on these drawings without any creative effort.

FIG. 1 is a schematic plan diagram of a circuit board according to the embodiments of the present disclosure, where a via is provided when an interlayer jumper is required, a conducting portion is provided in the via to connect two electrical conduction layers.

FIG. 2 is a schematic cross-sectional diagram of a circuit board according to the embodiments of the present disclosure, where a first conducting portion and a second conducting portion of a different insulating layer are both located on a same straight line in a longitudinal direction.

FIG. 3 is a schematic plan diagram of a circuit board according to the embodiments of the present disclosure, where conducting portions are provided to connect a pad with a thermal conduction layer and to connect adjacent thermal conduction layers.

FIG. 4 is a schematic cross-sectional view of a circuit board according to the embodiments of the present disclosure, where two first conducting portions and two second conducting portions of each insulating layer form two conducting lines parallel to each other.

FIG. 5 is a schematic cross-sectional diagram of a circuit board according to the embodiments of the present disclosure, where second conducting portions between a first thermal conduction layer and an adjacent second thermal conduction layer are provided on two sides of a first hollow portion, and the rest of the second conducting portions and the first conducting portion are located on a same straight line in a longitudinal direction.

FIG. 6 is a schematic cross-sectional diagram of a circuit board according to the embodiments of the present disclosure, where a distance between two second conducting portions gradually increases in a direction away from the pad.

FIG. 7 is a schematic cross-sectional diagram of a circuit board according to the embodiments of the present disclosure, where a third conducting portion is provided between two second thermal conduction portions.

FIG. 8 is a schematic plan diagram of a circuit board according to the embodiments of the present disclosure, where a third conducting portion is provided between two second thermal conduction portions and a first hollow portion is provided on the first thermal conduction layer.

FIG. 9 is a schematic cross-sectional diagram of a circuit board according to the embodiments of the present disclosure, where a cross-sectional area of a conducting portion gradually increases from a middle portion of the conducting portion toward two ends of the conducting portion.

FIG. 10 is a schematic plan diagram of a circuit board according to the embodiments of the present disclosure, where an edge of the circuit board exceeding a side of a display panel in a transverse direction forms an exposed portion.

FIG. 11 is a schematic plan diagram of a circuit board according to the embodiments of the present disclosure, where edges of the circuit board exceeding two sides of a display panel in a transverse direction form two exposed portions.

FIG. 12 is a sectional diagram of FIG. 11 taken along line A-A.

### DETAILED DESCRIPTION OF EMBODIMENTS

Exemplary embodiments will now be described more completely with reference to the accompanying drawings. However, exemplary embodiments may be embodied in various forms and should not be construed as being limited to the embodiments set forth here. Rather, these embodiments are provided so that the present disclosure will be thorough and complete and the concept of the exemplary embodiments may be fully conveyed to those skilled in the art. The same reference signs in the drawings indicate the same or similar structures, and thus the detailed descriptions thereof will be omitted. Furthermore, the drawings are merely schematic illustrations of the present disclosure and are not necessarily drawn to scale.

Although relative terms such as “upper” and “lower” are used in the specification to describe a relative relationship of one component to another component in the drawings, these terms are used in the specification only for convenience, such as according to directions of examples described in the drawings. It may be understood that if the illustrated device is turned upside down, a component described as being on an “upper” portion will become a component on a “lower” portion. When a structure is “on” the other structure, it may mean that the structure is integrally formed on the another structure, or the structure is “directly” arranged on the another structure, or the structure is “indirectly” arranged on the another structure through another structure.

The terms “one”, “a/an”, “the”, “said” and “at least one” are used to indicate a presence of one or more elements, components, etc. The terms “include” and “have” are used to express an open-ended inclusion and mean that additional elements, components, etc. may be present in addition to the listed elements, components, etc. The terms “first”, “second”, “third” etc. are used only as marks, and are not intended to limit the numbers of the objects.

Application scenarios of OLED display modules have gradually expanded from consumer electronics products to aviation, automotive, industrial control and the like. The typical characteristics of these scenarios are that the display module has a long lighting time and a relatively harsh operating environment, especially in a high-temperature environment, which may cause high heat generation in a power management chip 20, inductor, and MOS on a circuit board 100. As a result, heat in areas where pads of these components are located may not be effectively dissipated, which easily forms high-temperature hot spots. In severe cases, this may cause the display function problem of yellowing of the display region of the display panel, which seriously affects the user experience.

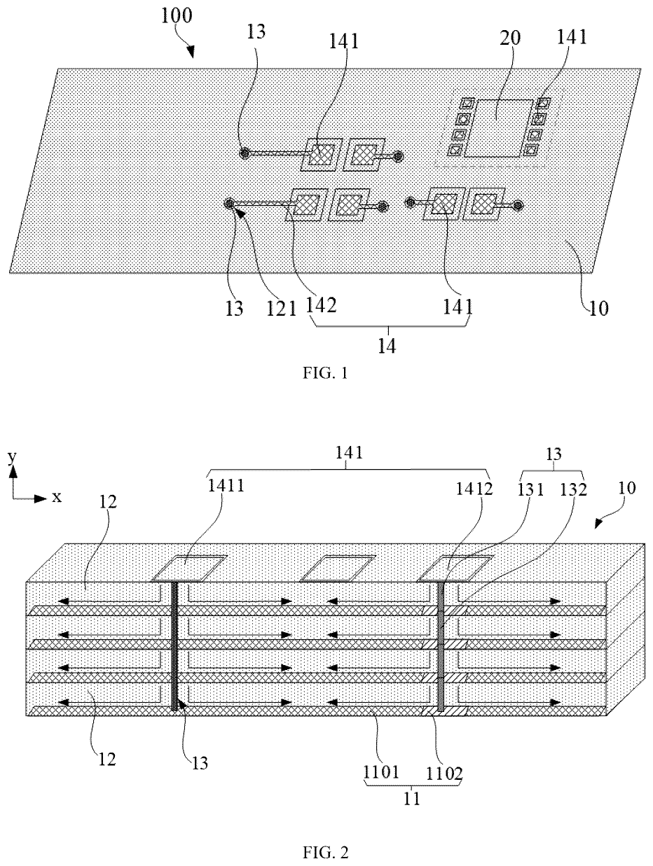

As shown in FIG. 1, a binding layer 14 includes a pad 141 and a lead 142. A layout design of the pad 141 and the lead 142 does not take into account a heat dissipation problem of the heat-generating device pad 141. A via 121 is only provided when an interlayer jumper is required on the lead 142. A conducting portion 13 is provided in the via 121 to connect two electrical conduction layers. As a result, heat on the pad 141 may not be effectively dissipated. A highest temperature on a region of the pad 141 may reach 58 °C, while an average temperature in other regions is 40 °C. If a heat transfer capability inside the circuit board 100 may be improved to distribute the heat evenly on the circuit board 100, the highest temperature on the circuit board 100 may inevitably be greatly reduced, thereby avoiding the problem of yellowing of the display region of the display panel.

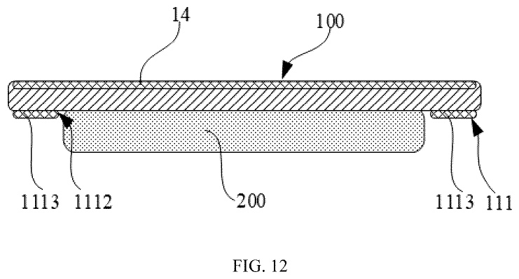

On this basis, the embodiments of the present disclosure provide a circuit board 100. As shown in FIG. 2 to FIG. 12, the circuit board 100 includes a circuit board body 10 and a binding layer 14. The binding layer 14 is provided on a side of the circuit board body 10 and includes a pad 141 used to bind an electronic component, and a lead connected to the pad 141 and used to transmit an electrical signal to the pad 14 or to transmit an electrical signal from the pad 14 to an interior of the circuit board. The circuit board body 10 includes at least two thermal conduction layers 11, insulating layers 12 are respectively provided between the pad 141 and the thermal conduction layer 11 and between two adjacent thermal conduction layers 11, the insulating layer 12 is provided with a via 121 filled with a conducting portion 13, the conducting portion between the pad 141 and the thermal conduction layer 11 is a first conducting portion 131 respectively connected to the pad 141 and the thermal conduction layer 11, the conducting portion between two adjacent thermal conduction layers 11 is a second conducting portion 132 respectively connected to the two adjacent thermal conduction layers 11. At least two of any two conducting portions 13 adjacent along a longitudinal direction are staggered with each other, and the longitudinal direction is a thickness direction of the circuit board body 10.

The circuit board body 10 includes at least two thermal conduction layers 11, the first conducting portion 131 is respectively connected to the pad 141 and the thermal conduction layer 11, and the second conducting portion 132 is respectively connected to two adjacent thermal conduction layers 11. The heat of the pad 141 may be transferred to the thermal conduction layer 11 through the first conducting portion 131, and the heat may be transferred among the thermal conduction layers 11 through the second conducting portion 132, so that the heat may be transferred longitudinally among the thermal conduction layers 11. At least two of any two conducting portions 13 adjacent along the longitudinal direction are staggered with each other, so that the heat may be spread and dissipated through the thermal conduction layers 11, thereby effectively improving a transverse transfer and a longitudinal transfer of the heat inside the circuit board 100, avoiding the high temperature from being concentrated on a certain point, and further avoiding the problem of yellowing of display of the display panel caused by high-temperature hot spots.

It should be noted that the pad 141 is a part of an electrical conduction circuit, and the first conducting portion 131, the second conducting portion 132 and each thermal conduction layer 11 only serve as thermal conduction structures of the pad 141, they are disconnected from other leads and electronic components in the electrical conduction circuit, and therefore, do not constitute a loop.

The circuit board 100 related to implementations of the present disclosure will be described in detail below with reference to the specific embodiments.

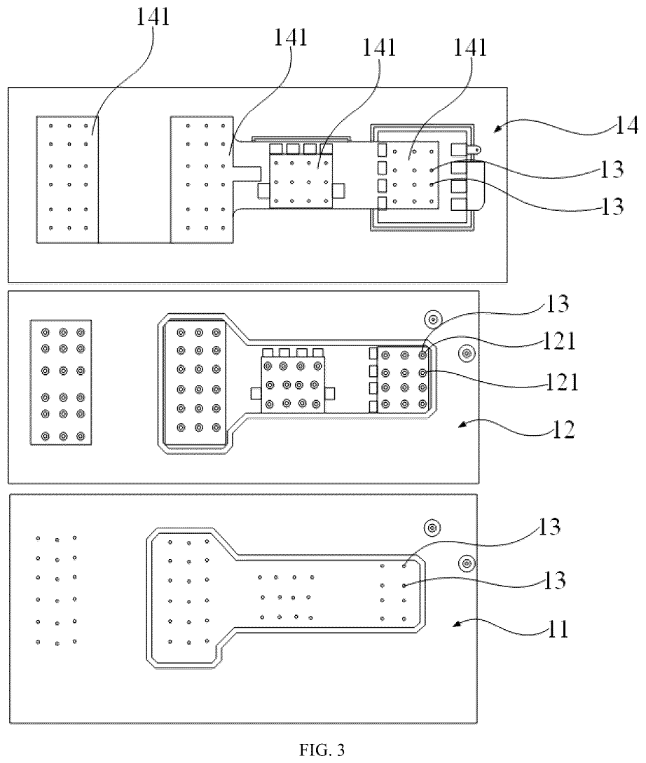

As shown in FIG. 2 and FIG. 3, the circuit board 100 includes a binding layer 14 and a plurality of thermal conduction layers 11 arranged in sequence along a thickness direction of the circuit board 100. The binding layer 14 includes a pad 141. An insulating layer 12 is provided between the pad 141 and the thermal conduction layer 11 and between two adjacent thermal conduction layers 11. The pad 141 and the thermal conduction layer 11 are attached to adjacent insulating layers 12. A via 121 is provided between the pad 141 and the thermal conduction layer 11 and between two adjacent thermal conduction layers 11. The via 121 is filled with a conducting portion 13 to connect the pad 141 with the thermal conduction layer 11 and connect the two adjacent thermal conduction layers 11. Specifically, a first via is provided in the insulating layer 12 between the pad 141 and the thermal conduction layer 11. The first via is filled with a first conducting portions 131. The first conducting portion 131 is respectively connected to the pad 141 and the thermal conduction layer 11. A second via is provided in the insulating layer 12 between two adjacent thermal conduction layers 11. The second via is filled with a second conducting portion 132. The second conducting portion 132 is respectively connected to the two adjacent thermal conduction layers 11.

The pad 141 includes a first pad 1411 and a second pad 1412, and the lead includes a reference signal line and a high-level signal line. The reference signal line is connected to the first pad 1411 and used to input a reference signal to the first pad 1411. The high-level signal line is connected to the second pad 1412 and used to input a high-level signal to the second pad 1412. A voltage of the high-level signal is greater than a voltage of the reference signal. The thermal conduction layer 11 includes a first thermal conduction sub-layer 1101 and a second thermal conduction sub-layer 1102 insulated from the first thermal conduction sub-layer 1101. The thermal conduction layer 11 may be provided as an entire layer. A shape and a size of the first thermal conduction sub-layer 1101 complement a shape and a size of the second thermal conduction sub-layer 1102. In the embodiment, specifically, the first thermal conduction sub-layer 1101 is formed by providing an opening on the thermal conduction layer 11, and the second thermal conduction sub-layer 1102 is provided in the opening. The shape and the size of the second thermal conduction sub-layer 1102 may be the same as a shape and a size of the second pad 1412. A gap is formed between an edge of the second thermal conduction sub-layer 1102 and an edge of the opening, and an insulating portion is filled in the gap.

As shown in FIG. 3, the first via is provided between the first pad 1411 and the first thermal conduction sub-layer 1101. The first via is filled with the first conducting portion 131 respectively connected to the first pad 1411 and the first thermal conduction sub-layer 1101, the first via is further provided between the second pad 1412 and the second thermal conduction sub-layer 1102, and the first via is filled with the first conducting portion 131 respectively connected to the second pad 1412 and the second thermal conduction sub-layer 1102. The first conducting portion 131 and the second conducting portions 132 of different insulating layer 12 are all located on a same straight line along the longitudinal direction.

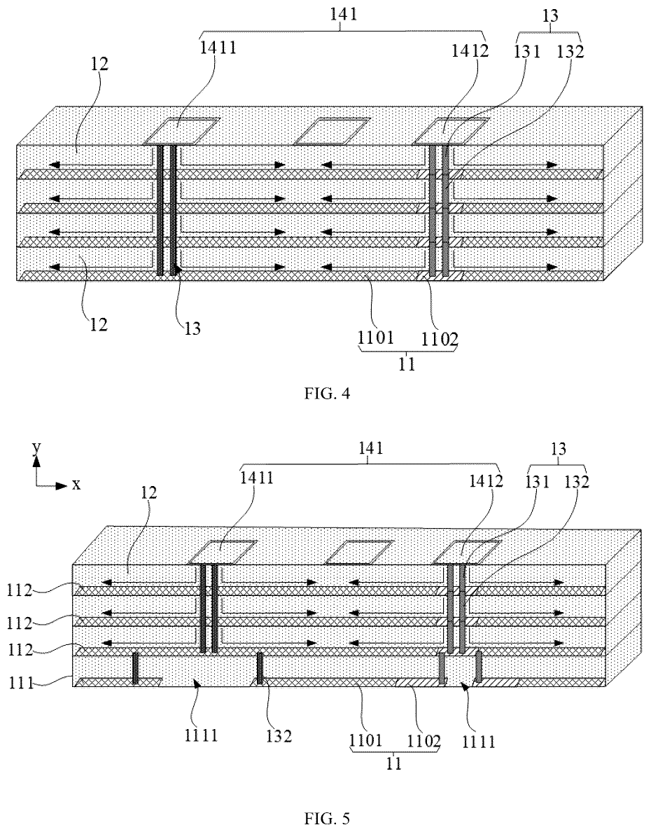

The number of conducting portions 13 provided in each insulating layer 12 is not specifically limited, the number is specifically related to a relative size of an area of the pad 141 and a cross-sectional area of the conducting portion 13. As shown in FIG. 4, two first conducting portions 131 are provided between the first pad 1411 and the first thermal conduction sub-layer 1101, and second conducting portions 132 identical in number as the first conducting portions 131 are provided between every two adjacent first thermal conduction sub-layers 1101. The two first conducting portions 131 and the two second conducting portions 132 of each insulating layer 12 form two conducting lines parallel to each other. Orthographic projections of the second pad 1412 and a plurality of second thermal conduction sub-layers 1102 on the circuit board body 10 overlap with one another. Two first conducting portions 131 are provided between the second pad 1412 and the second thermal conduction sub-layer 1102. Second conducting portions 132 identical in number as the first conducting portions 131 are provided between every two adjacent second thermal conduction sub-layer 1102. The two first conducting portions 131 and the two second conducting portions 132 of each insulating layer 12 form two conducting lines parallel to each other.

As shown in FIG. 5, when the circuit board 100 is applied to a display module, the circuit board 100 is usually attached to a display panel. Therefore, it is necessary to reduce heat conducted to the display region of the display panel. The thermal conduction layer 11 farthest from the pad 141 is defined as a first thermal conduction layer 111, and the rest of the thermal conduction layers 11 are defined as second thermal conduction layers 112. A first hollow portion 1111 is provided on the first thermal conduction layer 111, and an orthographic projection of the pad 141 on the first thermal conduction layer 111 is located within the first hollow portion 1111. A portion of the first thermal conduction layer 111 located in the first hollow portion 1111 is completely etched away, which may reduce the heat conducted to the display region of the display panel, and may further alleviate the problem of yellowing of the display region of the display panel.

For the first pad 1411, the first hollow portion 1111 is arranged on the first thermal conduction sub-layer 1101 of the first thermal conduction layer 111, and an orthographic projection of the first pad 1411 on the first thermal conduction layer 111 is located within the first hollow portion 1111 of the first thermal conduction sub-layer 1101. For the second pad 1412, the first thermal conduction layer 111 is provided with two second thermal conduction sub-layers 1102, the first hollow portion 1111 is arranged between the two second thermal conduction sub-layers 1102, and an orthographic projection of the second pad 1412 on the first thermal conduction layer 111 is located within the first hollow portion 1111 between the two second thermal conduction sub-layers 1102. Regardless of the first pad 1411 or the second pad 1412, the second conducting portions 132 between the first thermal conduction layer 111 and the adjacent second thermal conduction layer 112 are provided on two sides of the first hollow portion 1111, and the rest second conducting portions 132 and the first conducting portions 131 are located on the same straight line along the longitudinal direction. It should be noted that the longitudinal direction is the thickness direction of the circuit board 100.

For the first conducting portion 131 and the second conducting portion 132 that are adjacent to each other and located on the same straight line, heat is transferred in a manner as follows: the heat on the pad 141 is transferred to the first conducting portion 131, the heat on the first conducting portion 131 is directly transferred to a closest second conducting portion 132, and then the heat is transferred to another second conducting portions 132 by the closest second conducting portion 132. The heat of the pad 141 may be quickly transferred longitudinally to a side of the circuit board body 10 away from the pad 141. Obviously, the circuit board 100 with such structure has better thermal conductivity in the longitudinal direction. The longitudinal direction refers to a y direction in the drawing.

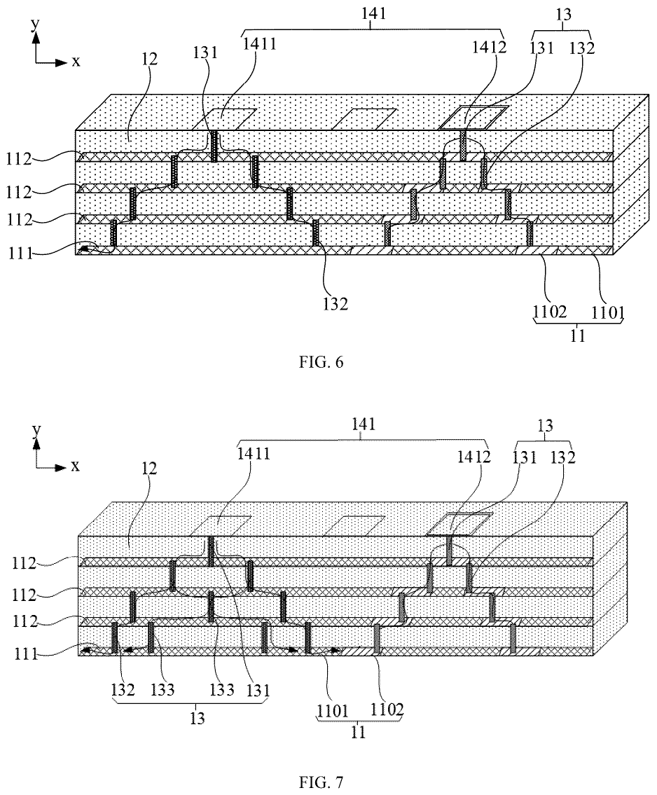

As shown in FIG. 6, a first conducting portion 131 is provided between the pad 141 and the thermal conduction layer 11, and two second conducting portions 132 are provided between two adjacent thermal conduction layers 11. The two second conducting portions 132 are symmetrically arranged on two sides of the first conducting portion 131, and a distance between two second conducting portions 132 gradually increases in a direction away from the pad 141. The heat is transferred from the pad 141 to the first conducting portion 131, then transferred from the first conducting portion 131 to two second conducting portions 132 of the adjacent thermal conduction layer 11 in a transverse direction, and further transferred from the two second conducting portions 132 of the thermal conduction layer 11 to two second conducting portions 132 of another thermal conduction layer 11 farther from the pad 141. The first conducting portion 131 and the second conducting portions 132 form a tree-like heat conduction path radiating towards a periphery of the circuit board 100, which is more conducive to dissipation of the heat to the surroundings, and further enhancing uniformity of heat distribution across the circuit board 100. The transverse direction refers to a x direction in the drawing.

It should be emphasized that, for the second pad 1412, the numbers and positions of the openings and the second thermal conduction sub-layers 1102 need to be adjusted to ensure that the first conducting portion 131 may connect the first pad 1411 with the second thermal conduction sub-layer 1102 of the first thermal conduction layer 111, and the second conducting portion 132 may connect the second thermal conduction sub-layers 1102 of two adjacent second thermal conduction layers 112. As shown in FIG. 6, a distance between the two second thermal conduction sub-layers 1102 gradually increases in a direction away from the second pad 1412. For the first pad 1411, since the first thermal conduction sub-layer 1101 occupies a larger proportion in the thermal conduction layer 11, when an arrangement of the conducting portion 13 changes, a connection between the first conducting portion 131 and the second conducting portion 132 may usually be satisfied without adjustment.

As shown in FIG. 7, a third via is provided between the second vias of at least some of the insulating layers 12. The third via is filled with a third conducting portion 133. The third conducting portion 133 is respectively connected to two adjacent thermal conduction layers 11. The third conducting portion 133 is provided between two second conducting portions 132 of a same insulating layer 12. This may increase the number of conducting portions 13 between adjacent thermal conduction layers 11, thereby further enhancing the thermal conductivity of the circuit board 100 in the longitudinal direction. This may also reduce the distance between two adjacent conducting portions 13, thereby facilitating the heat transfer from a conducting portion 13 to another adjacent conducting portion 13, and further enhancing the thermal conductivity of the circuit board 100 in the transverse direction.

The number of the third conducting portions 133 gradually increases in the direction away from the pad 141. It may be understood that the greater the distance between two second thermal conduction portions, the greater the number of the third thermal conduction portions 133 provided between the two second thermal conduction portions. When the number of the second conducting portions 132 remains unchanged, it may be ensured that a total number of the conducting portions 13 increases in the direction away from the pad 141, so that the heat may be gradually dissipated in the transverse and longitudinal directions inside the circuit board 100, thereby further improving the heat dissipation uniformity of the circuit board 100.

In any two adjacent insulating layers 12 along the longitudinal direction, the number of the third conducting portions 133 is set alternately in an even number and an odd number. When the number of the third conducting portions 133 is an odd number, one of the third conducting portions 133 is located on the same straight line as the first conducting portion 131 along the longitudinal direction. When the number of the third conducting portions 133 is an even number, the third conducting portions 133 are symmetrically arranged on two sides of the first conducting portion 131. In the same insulating layer 12, the distance between any two adjacent conducting portions 13 is equal, and the distance between adjacent conducting portions 13 gradually decreases in the direction away from the pad 141, so that a density of the conducting portions 13 increases uniformly in the longitudinal direction away from the pad 141, the thermal conductivity efficiency of the circuit board 100 is gradually enhanced, and an thermal conductivity efficiency may not be affected while dissipating heat.

From top to bottom along the longitudinal direction, a first insulating layer 12, a second insulating layer 12, a third insulating layer 12 and a fourth insulating layer 12 are arranged in sequence. The third insulating layer 12 is provided with a third conducting portion 133, and the fourth insulating layer 12 is provided with two third conducting portions 133. The third conducting portion 133 of the third insulating layer 12 is located on the same straight line as the first conducting portion 131 along the longitudinal direction. The third conducting portions 133 of the fourth insulating layer 12 are symmetrically arranged on two sides of the third conducting portion 133 of the third insulating layer 12, and the third conducting portion 133 of the fourth insulating layer 12 is located between the second conducting portion 132 of the second insulating layer 12 and the second conducting portion 132 of the third insulating layer 12 that are adjacent to each other in the transverse direction.

Along the direction away from the pad 141, the first insulating layer 12 is provided with a first conducting portion 131, the second insulating layer 12 is provided with two second conducting portions 132, the third insulating layer 12 is provided with three conducting portions 13, and the fourth insulating layer 12 is provided with four conducting portions 13. The number of the conducting portions 13 gradually increases in the direction away from the pad 141, and the distance between the conducting portions 13 gradually decreases. A plurality of conducting portions 13 may form a grid-like heat transfer path inside the circuit board 100, thereby further improving the heat distribution uniformity of the circuit board 100 compared with a tree-like transfer path.

In FIG. 7, a small amount of heat is directly transferred to the display region of the display panel. Therefore, as shown in FIG. 8, the first hollow portion 1111 is provided on the first thermal conduction layer 111 to avoid affecting the heat conduction inside the circuit board 100. The first thermal conduction layer 111 is usually provided with an even number of third conducting portions 133, and the first hollow portion 1111 is arranged between two third conducting portions 133 closest to the straight line where the first conducting portion 131 is located. An orthographic projection of the pad 141 on the first thermal conduction layer 111 is located within the first hollow portion 1111. A portion of the first thermal conduction layer 111 located in the first hollow portion 1111 is completely etched away, which may reduce the heat conducted to the display region of the display panel, and further alleviate the problem of yellowing of the display region of the display panel.

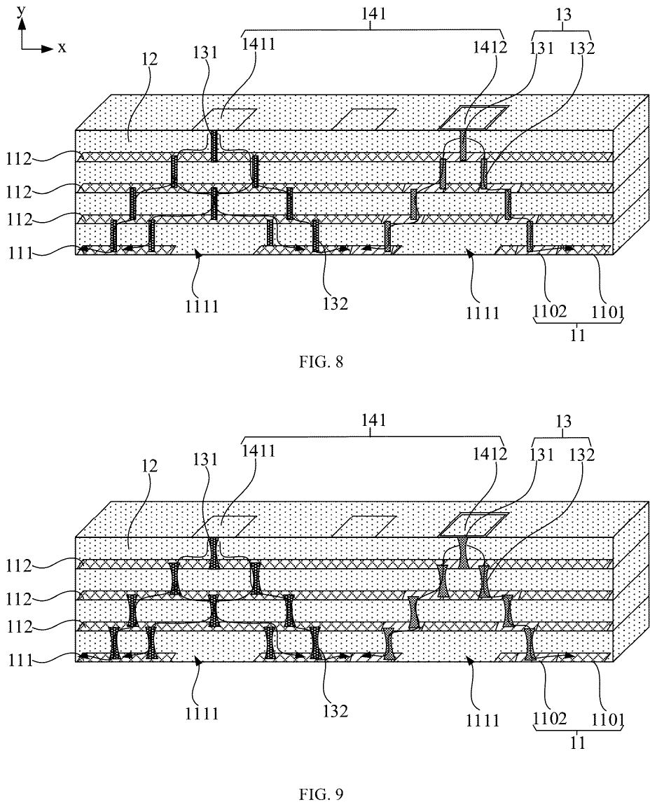

As shown in FIG. 9, a cross-sectional area of each of the first conducting portion 131, the second conducting portion 132, and the third conducting portion 133 may be set to gradually increase from a middle portion to two ends thereof. It may be understood that two ends of the conducting portion 13 is in contact with the pad 141 and the thermal conduction layer 11, and cross-sectional areas of two ends of the conducting portion 13 are the largest, which may enhance the thermal conductivity of the conducting portion 13. The middle portion of the conducting portion 13 is in contact with the insulating layer 12. The thermal conductivity of the insulating layer 12 is poorer than the thermal conductivity of the thermal conduction layer 11. A size of the middle portion of the conducting portion 13 is smaller, which may reduce a probability of heat transfer through the insulating layer 12, therefore allowing the heat to be conducted away through the thermal conduction layer 11 as much as possible, thus further improving the heat dissipation capacity of the circuit board 100.

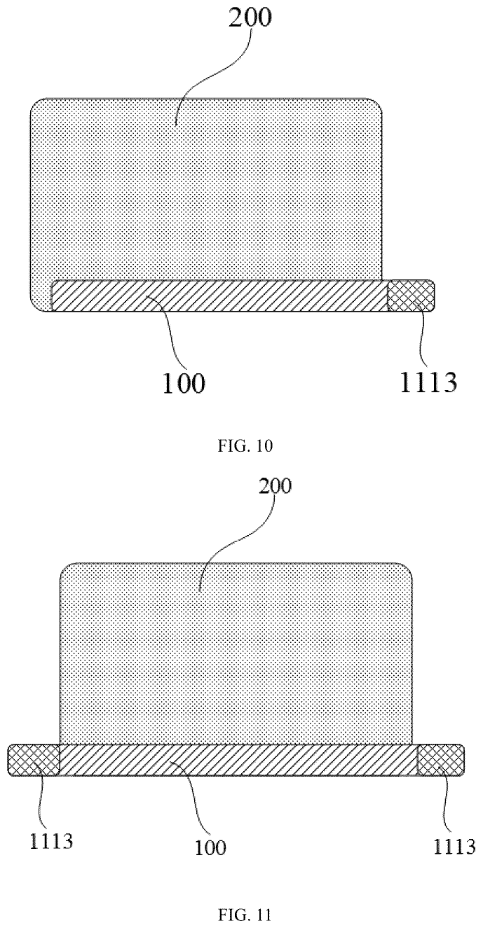

The implementations of the present disclosure further provide a display device. As shown in FIG. 10 to FIG. 12, the display device may include a display module and the circuit board 100 involved in the above implementations of the present disclosure. The display module includes a display panel 200, a middle frame and a heat dissipation mechanism. The circuit board 100 is connected to the display panel 200. An edge of the circuit board 100 exceeding at least one side of the display panel 200 in a transverse direction forms an exposed portion 1113 connected to the middle frame or the heat dissipation mechanism. The exposed portion 1113 may also be connected to both the middle frame and the heat dissipation mechanism, so as to further improve the heat dissipation effect of the display device.

The specific structure and the beneficial effects of the circuit board 100 are described in detail above, and therefore may not be repeated here. It should be noted that, in addition to the circuit board 100, the display device also includes other necessary components, such as a housing, a power line, and the like. Those skilled in the art may make corresponding supplements based on the specific usage requirements of the display device, which will not be repeated here.

In a case that the circuit board 100 is of the structures shown in the drawings, the display device may be a traditional electronic apparatus, such as a mobile phone, a computer, a television, and a camcorder, or it may be an emerging wearable apparatus, such as a virtual reality apparatus and an augmented reality apparatus, which will not be listed here one by one.

As shown in FIG. 10, the thermal conduction layer 11 closest to the display panel 200 is the first thermal conduction layer 111. The first thermal conduction layer 111 exceeds an edge of a side of the display panel 200 in the transverse direction. The exposed portion 1113 is located on a portion of the first thermal conduction layer 111 exceeding the display panel 200. Direct lapping of the first thermal conduction layer 111 on the middle frame (not shown in FIG. 10) or the heat dissipation mechanism (not shown in FIG. 10) may further enhance the heat dissipation capability of the display device. As shown in FIG. 11, on this basis, in order to further enhance capability of the display device, the first thermal conduction layer 111 exceeds two side edges of the display panel 200 in the transverse direction, and two exposed portions 1113 may be formed to be connected to the middle frame and the heat dissipation mechanism.

As shown in FIG, 12, a second hollow portion 1112 may be provided on the first thermal conduction layer 111, an orthographic projection of the display panel 200 on the first thermal conduction layer 111 is located within the second hollow portion 1112, the exposed portions 1113 are located on two sides of the second hollow portion 1112. The first thermal conduction layer 111 is completely removed or patterned in the second hollow portion 1112, and the first thermal conduction layer 111 is retained at the exposed portions 1113. This not only reduces the heat transferred to the display panel 200, but also facilitates the transfer of heat to the middle frame or the heat dissipation mechanism. Therefore, the high-temperature hot spots and the heat transferred to the display panel may be greatly reduced, thereby avoid yellowing of the display region of the display panel 200.

Other implementations of the present disclosure will be apparent to those skilled in the art after consideration of the specification and practice of the present disclosure. The present disclosure is intended to cover any modifications, uses or adaptive changes of the present disclosure. These modifications, uses or adaptive changes follow the general principles of the present disclosure and include common knowledge or common technical means in the art that are not disclosed in the present disclosure. The specification and the embodiments are considered as exemplary only, and the true scope and spirit of the present disclosure are indicated by the appended claims.

1. A circuit board, comprising:
a circuit board body;
a binding layer on a side of the circuit board body, wherein the binding layer comprises a pad and a lead, the pad is configured to bind an electronic component, the lead is connected to the pad and configured to transmit an electrical signal to the pad, or transmit an electrical signal from the pad to an interior of the circuit board;
wherein,
the circuit board body comprises at least two thermal conduction layers, an insulating layer is provided between the pad and one of the at least two thermal conduction layers or between two adjacent thermal conduction layers, the insulating layer are provided with a via filled with a conducting portion, the conducting portion between the pad and the thermal conduction layer is a first conducting portion respectively connected to the pad and the thermal conduction layer, the conducting portion between two adjacent thermal conduction layers is a second conducting portion respectively connected to the two adjacent thermal conduction layers, at least two of any two conducting portions adjacent along a longitudinal direction are staggered with each other, and the longitudinal direction is a thickness direction of the circuit board body.

2. The circuit board according to claim 1, wherein the pad comprises a first pad, the lead comprises a reference signal line connected to the first pad and configured to input a reference signal to the first pad, the thermal conduction layer comprises a first thermal conduction sub-layer, a first via is provided between the first pad and the first thermal conduction sub-layer, the first via is filled with the first conducting portion, and the first conducting portion is respectively connected to the first pad and the first thermal conduction sub-layer.

3. The circuit board according to claim 2, wherein the pad comprises a second pad, the lead comprises a high-level signal line connected to the second pad and configured to input a high-level signal to the second pad, the thermal conduction layer comprises a second thermal conduction sub-layer, the second thermal conduction sub-layer is insulated from the first thermal conduction sub-layer, the first via is further provided between the second pad and the second thermal conduction sub-layer, the first via is filled with the first conducting portion, and the first conducting portion is respectively connected to the second pad and the second thermal conduction sub-layer.

4. The circuit board according to claim 1, wherein at least two first conducting portions are provided between the pad and the thermal conduction layer, and second conducting portions identical in number as the first conducting portions are provided between every two adjacent thermal conduction layers, each of the at least two first conducting portions and each of the second conducting portions closest to the first conducting portion is located on a same straight line in a longitudinal direction, and the longitudinal direction is the thickness direction of the circuit board body.

5. The circuit board according to claim 1, wherein at least one first conducting portion is provided between the pad and the thermal conduction layer, and two second conducting portions are provided between two adjacent thermal conduction layers and located on two sides of the first conducting portion, and a distance between two second conducting portions gradually increases in a direction away from the pad.

6. The circuit board according to claim 4, wherein the thermal conduction layer farthest from the pad is a first thermal conduction layer, a first hollow portion is provided on the first thermal conduction layer, and an orthographic projection of the pad on the first thermal conduction layer is located within the first hollow portion.

7. The circuit board according to claim 6, wherein the rest of the thermal conduction layers are second thermal conduction layers, and the second conducting portions between the first thermal conduction layer and an adjacent second thermal conduction layer are provided on two sides of the first hollow portion.

8. The circuit board according to claim 1, wherein a third via is provided between second vias of at least part of insulating layers, the third via is filled with a third conducting portion, the third conducting portion is respectively connected to two adjacent thermal conduction layers, and the third conducting portion is provided between two second conducting portions of a same insulating layer.

9. The circuit board according to claim 8, wherein the number of the third conducting portion gradually increases in a direction away from the pad.

10. The circuit board according to claim 9, wherein in the same insulating layer, a distance between any two adjacent conducting portions is equal, and the distance between adjacent conducting portions gradually decreases in the direction away from the pad.

11. The circuit board according to claim 10, wherein the number of the third conducting portions is alternately provided in an even number and an odd number, the thermal conduction layer farthest from the pad is provided with an even number of third conducting portions, and a first hollow portion is provided between two third conducting portions closest to a straight line where the first conducting portion is located.

12. The circuit board according to claim 1, wherein a cross-sectional area of the first conducting portion gradually increases from a middle portion of the first conducting portion toward two ends of the first conducting portion, and a cross-sectional area of the second conducting portion gradually increases from a middle portion of the second conducting portion toward two ends of the second conducting portion.

13. A display device, comprising:
a display module, comprising a display panel, a middle frame and a heat dissipation mechanism; and
the circuit board according to claim 1, wherein the circuit board is connected to the display panel, an edge of the circuit board exceeding at least one side of the display panel in a transverse direction to form an exposed portion connected to the middle frame and/or the heat dissipation mechanism.

14. The display device according to claim 13, wherein the thermal conduction layer closest to the display panel is the first thermal conduction layer, and the exposed portion is located on a portion of the first thermal conduction layer exceeding at least one side edge of the display panel in the transverse direction.

15. The display device according to claim 14, wherein the first thermal conduction layer is provided with a second hollow portion, an orthographic projection of the display panel on the first thermal conduction layer is located within the second hollow portion, and exposed portions are located on two sides of the second hollow portion.
